(19) United States
(12) Patent Application Publication
(10) Pub. No.: US 2021/0210527 A1
(43) Pub. Date: Jul. 8, 2021

(54) DISPLAY DEVICE, ARRAY SUBSTRATE AND MANUFACTURING METHOD THEREOF

(71) Applicants: BOE TECHNOLOGY GROUP CO., LTD., Beijing (CN); BEIJING BOE DISPLAY TECHNOLOGY CO., LTD., Beijing (CN)

(72) Inventors: Jinchao BAI, Beijing (CN); Xiao HAN, Beijing (CN); Qi SANG, Beijing (CN); Huibin GUO, Beijing (CN); Yongzhi SONG, Beijing (CN)

(21) Appl. No.: 16/074,185

(22) PCT Filed: Dec. 14, 2017
(86) PCT No.: PCT/CN2017/116074

§ 371 Date: Jul. 31, 2018

(30) Foreign Application Priority Data
May 12, 2017 (CN) 201710335389.9

(51) Int. Cl. H01L 27/12; G02F 1/1362; G02F 1/1343; G02F 1/1335

(52) U.S. Cl. CPC H01L 27/1259; G02F 1/136227; G02F 1/13439; G02F 1/13629; G02F 1/136295; H01L 27/124; G02F 2203/02; G02F 1/133553

(57) ABSTRACT

A method for manufacturing an array substrate, including forming a thin film transistor and a peripheral circuit; forming a passivation layer covering at least the thin film transistor and the peripheral circuit; forming a first via hole penetrating the passivation layer and exposing part of a drain of the thin film transistor, and a second via hole penetrating the passivation layer and exposing part of the peripheral circuit; forming a first conductive layer pattern on the passivation layer, the first conductive layer pattern covering the first via hole and the second via hole; forming a reflective metal layer pattern and a second conductive layer pattern on the first conductive layer pattern, the second conductive layer pattern covering the second via hole.

### RELATED APPLICATION

The present application is the U.S. national phase entry of PCT/CN2017/116074, with an international filling date of Dec. 14, 2017, which claims the benefit of Chinese Patent Application No. 201710335389.9, filed on May 12, 2017, the entire disclosure of which is incorporated herein by reference.

### TECHNICAL FIELD

The present disclosure generally relates to the field of display technologies, and specifically to a display device, an array substrate, and a method for manufacturing an array substrate.

### BACKGROUND

At present, in the field of display devices, thin film transistor liquid crystal displays (TFT-LCDs) have been widely used due to their characteristics such as small size, low power consumption, and so on. Liquid crystal displays generally can be classified into two types: transmissive liquid crystal displays and reflective liquid crystal displays. The array substrate of a liquid crystal display generally includes a base substrate as well as thin film transistors, a peripheral circuit, via holes, and the like formed on the base substrate. The via holes connect electrically conductive structures in different layers. However, for the existing array substrates, poor contact at the via holes often occurs.

### SUMMARY

According to an exemplary embodiment of the present disclosure, a method for manufacturing an array substrate is provided, which includes the steps of: forming a thin film transistor and a peripheral circuit, forming a passivation layer covering at least the thin film transistor and the peripheral circuit, forming a first via hole penetrating the passivation layer and exposing part of a drain of the thin film transistor and a second via hole penetrating the passivation layer and exposing part of the peripheral circuit, forming a first conductive layer pattern on the passivation layer, the first conductive layer pattern covering the first via hole and the second via hole, and forming a reflective metal layer pattern and a second conductive layer pattern on the first conductive layer pattern, the second conductive layer pattern covering the second via hole.

In some embodiments, forming the first conductive layer pattern, the second conductive layer pattern, and the reflective metal layer pattern includes forming a first conductive film on the passivation layer; forming a reflective metal film on the first conductive film; performing a patterning process to the reflective metal film to form a reflective metal layer pattern; forming a second conductive film covering at least the reflective metal layer pattern and the first conductive film, performing a patterning process to the first conductive film and the second conductive film to retain a portion of the first conductive film covered by the reflective metal layer pattern, and a portion of the first conductive film and a portion of the second conductive film that cover the second via hole.

In some embodiments, performing a patterning process to the first conductive film and the second conductive film includes performing a patterning process to the second conductive film to remove a portion of the second conductive film that does not cover the second via hole; performing a patterning process to the first conductive film to remove a portion of the first conductive film that is not covered by the reflective metal layer pattern and does not cover the second via hole.

In some embodiments, the first conductive layer pattern includes a first conductive sub-pattern and a second conductive sub-pattern, the first conductive sub-pattern being connected to the drain of the thin film transistor via the first via hole, and the second conductive sub-pattern being connected to a common pad of the peripheral circuit via the second via hole.

In some embodiments, the first conductive layer pattern and the second conductive layer pattern are made of a same material.

In some embodiments, the first conductive layer pattern and the second conductive layer pattern both includes a transparent conductive material.

In some embodiments, the reflective metal layer pattern and the first conductive sub-pattern overlap each other and cover the first via hole.

In some embodiments, the second conductive sub-pattern and the second conductive layer pattern overlap each other and cover the second via hole.

In some embodiments, the reflective metal layer constitutes a part of a pixel electrode of the array substrate.

Another exemplary embodiment of the present disclosure provides an array substrate including a base substrate, a thin film transistor on the base substrate, a peripheral circuit on the base substrate, a passivation layer covering at least the thin film transistor and the peripheral circuit, a first via hole penetrating the passivation layer and exposing part of a drain of the thin film transistor, a second via hole penetrating the passivation layer and exposing part of the peripheral circuit, a first conductive layer pattern disposed on the passivation layer and covering the first via hole and the second via hole, a second conductive layer pattern disposed on the passivation layer and covering the second via hole; a reflective metal layer pattern disposed on the first conductive layer pattern and covering the first via hole.

In some embodiments, the first conductive layer pattern and the second conductive layer pattern are made of a same material.

In some embodiments, the first conductive layer pattern and the second conductive layer pattern both include a transparent conductive material.

In some embodiments, the first conductive layer pattern includes a first conductive sub-pattern and a second conductive sub-pattern, the first conductive sub-pattern being connected to the drain of the thin film transistor via the first via hole, and the second conductive sub-pattern being connected to a common pad of the peripheral circuit via the second via hole.

In some embodiments, the reflective metal layer pattern and the first conductive sub-pattern overlap each other and cover the first via hole.

In some embodiments, the second conductive sub-pattern and the second conductive layer pattern overlap each other and cover the second via hole; the reflective metal layer constitutes a part of a pixel electrode of the array substrate.

A further exemplary embodiment of the present disclosure provides a display device including the array substrate as described in any of the foregoing embodiments.

It is to be understood that the above general description and the following detailed description are only intended to be exemplary and illustrative but not restrictive.

### BRIEF DESCRIPTION OF THE DRAWINGS

The drawings herein illustrate some embodiments of the present disclosure, which are used to explain the principles of the disclosure together with the description. The drawings mentioned in the description below are only part of the embodiments of the disclosure. Other drawings may be obtained by those ordinarily skilled in the art based on these drawings without inventive efforts.

FIG. 1 is a flow chart of a method for manufacturing an array substrate provided by an embodiment of the present disclosure.

FIG. 2 is a flow chart involved in the process of forming a first conductive layer pattern, a second conductive layer pattern, and a reflective metal layer pattern in the method for manufacturing an array substrate provided by an embodiment of the present disclosure.

FIGS. 3-11 illustrate various steps in the method for manufacturing an array substrate provided by an embodiment of the present disclosure.

### DETAILED DESCRIPTION OF EMBODIMENTS

Exemplary embodiments will now be described more comprehensively with reference to the accompanying drawings. However, the embodiments can be implemented in a variety of forms and should not be construed as being limited to the examples set forth herein; rather, these embodiments are provided so that the present disclosure will be more comprehensive and complete, and the concept of the exemplary embodiments will be communicated to those skilled in the art more comprehensively. The described features, structures, or characteristics may be combined in any suitable manner in one or more embodiments. In the description below, numerous specific details are set forth to provide full understanding of the embodiment in this disclosure. However, those skilled in the art will appreciate that one or more of the specific details may be omitted, or other methods, components, devices, steps, etc. may be adopted when implanting solutions described in the disclosure. Well-known technical features are not illustrated in detail or not described so as not to obscure various exemplary embodiments of the disclosure.

In this specification, relative terms such as “upper”, “above”, “over”, “lower”, “under” or “below” are used to describe the relative relationship of one component to another component, but these terms are used in this specification for convenience only, and these terms are based on the examples shown in the drawings. It can be understood that if a device shown in the drawings is turned over to make it upside down, the component described as an “upper” one will become a “lower” component. When a structure is “above” another structure, it is possible that a structure is integrally formed on the other structure, or a structure is “directly” disposed to the other structure, or a structure is “indirectly” disposed to the other structure via another structure.

The terms such as “a”, “an”, “the” and “said” are used to indicate the presence of one or more elements/components, and the like. The terms “including” and “having” mean an open-ended inclusion, and indicate that there may be additional elements/components other than the listed elements or components. The terms “first” and “second” are used to distinguish different objects, rather than to limit the numbers of objects they denote.

A reflective liquid crystal display can reflect light entering its interior, and employs it as a light source required for displaying an image so as to realize the display function. In this way, a dedicated backlight source can be omitted, which helps to reduce power consumption. Inventors of the disclosure have found that the reflective layer in the existing array substrate often covers a metal exposed by the via hole, such as a drain metal. When a reflective layer pattern is being formed by an etching process, the metal exposed by the via hole is easy to be etched, making it difficult for the structures in different layers to be normally electrically connected, which are supposed to be electrically connected through the via hole. That is, a poor contact at the via hole occurs. Even if the metal exposed by the via hole is covered by a conductive protection layer, it is possible that the conductive protective layer at the position where the via hole climbs is etched during the etching process for forming the reflective layer pattern, which also causes it difficult for the structures in different layers to be normally electrically connected, thus also resulting in poor contact at the via hole.

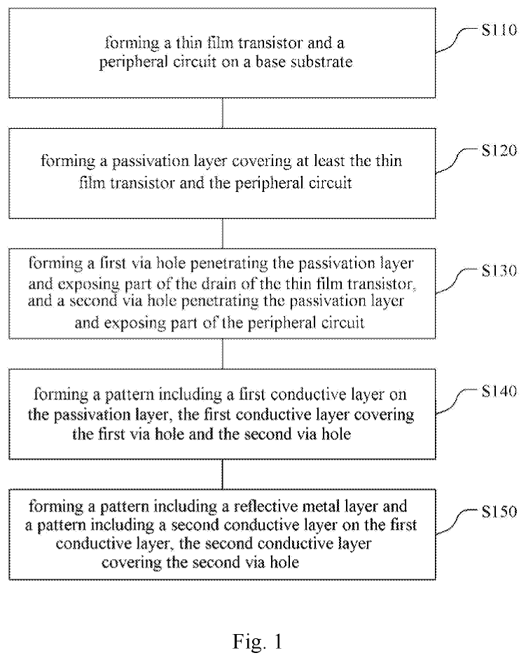

In view of the above problems, an embodiment of the present disclosure first provides a method for manufacturing an array substrate. As shown in FIG. 1, a method for manufacturing an array substrate according to an embodiment of the present disclosure includes the following steps:

S110, forming a thin film transistor and a peripheral circuit on a base substrate;

S120, forming a passivation layer covering at least the thin film transistor and the peripheral circuit;

S130, forming a first via hole penetrating the passivation layer and exposing part of the drain of the thin film transistor, and a second via hole penetrating the passivation layer and exposing part of the peripheral circuit;

S140, forming a pattern of a first conductive layer on the passivation layer, the first conductive layer covering the first via hole and the second via hole;

S150, forming a pattern of a reflective metal layer and a pattern of a second conductive layer on the first conductive layer, the second conductive layer covering the second via hole.

With the method for manufacturing an array substrate provided by this embodiment, when the reflective metal layer is being formed, the metal exposed by the first via hole and the second via hole can be protected by the first conductive layer to prevent etching the metal exposed by the first via hole and the second via hole. At the same time, since the second conductive layer is further formed on the first conductive layer, that is, the second conductive layer further covers the second via hole on the basis that the first conductive layer covers the second via hole, even if the first conductive layer at the position where the second via hole climbs is etched, good contact at the second via hole can also be realized by means of the second conductive layer. As a result, poor contact at the first via hole and the second via hole resulting from the formation of the reflective metal layer can be avoided, which is advantageous for improving the yield.

Each step of the method for manufacturing an array substrate in the exemplary embodiment will be further described below with reference to FIGS. 3 to 11.

In step S110, as shown in FIG. 3, a thin film transistor and a peripheral circuit are formed on a base substrate. The thin film transistor may be formed in a display area of a base substrate 1, and a peripheral circuit may be formed in a non-display area thereof.

The thin film transistor may include a gate 2, a gate insulating layer 3, an active layer 4, a source 5, a drain 6, and so on. The peripheral circuit may include a common pad 7 for connection with a driving circuit board, and so on. The gate 2 and the common pad 7 may be formed by a patterning process using only one mask and located in the same layer, and a common electrode may also be formed at the same time. The patterning process may be a classical mask process including steps of photoresist coating, exposure, development, etching, photoresist stripping, etc., or a mask process employing ions peeling technology, or other processes such as printing, as long as it can form the gate 2 and the common pad 7. No limitation is imposed on the patterning process in the disclosure.

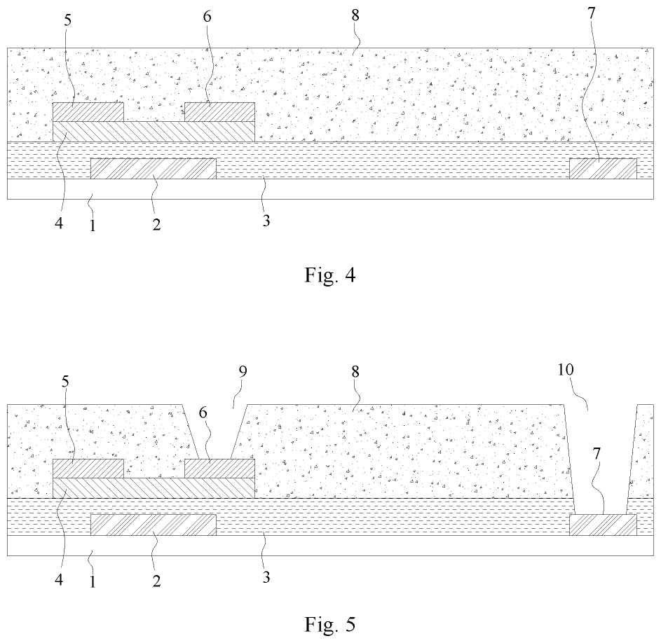

In step S120, as shown in FIG. 4, a passivation layer 8 covering at least the thin film transistor and the peripheral circuit is formed.

In this embodiment, the passivation layer 8 may be formed above the base substrate 1 on which the thin film transistor and the peripheral circuit have been formed, which covers the source 5 the drain 6 of the thin film transistor as well as the peripheral circuit, thereby providing protection effect. The passivation layer 8 may be formed of an insulating material, and the manner in which the passivation layer 8 is formed includes, but is not limited to, deposition, coating, sputtering, and the like.

In step S130, as shown in FIG. 5, a first via hole 9 penetrating the passivation layer 8 and exposing part of the drain of the thin film transistor, and a second via hole 10 penetrating the passivation layer 8 and exposing part of the peripheral circuit are formed.

In this embodiment, the first via hole 9 may be a via hole located in the display area and exposing part of the drain 6 of the thin film transistor, and may penetrate the passivation layer 8 to expose part of the drain 6. The second via hole 10 may be a via hole located in the non-display area and exposing part of the common pad 7 of the peripheral circuit, and may penetrate the passivation layer 8 and the gate insulating layer 3 to expose part of the common pad 7. As for the process for forming the first via hole 9 and the second via hole 10, reference may be made to the common practice of forming a via hole in the art, and details are not described herein. The above is only illustrative description of the first via hole 9 and the second via hole 10, and does not constitute a limitation to the first via hole 9 and the second via hole 10, and the first via hole 9 and the second via hole 10 are may also be other via holes of other forms.

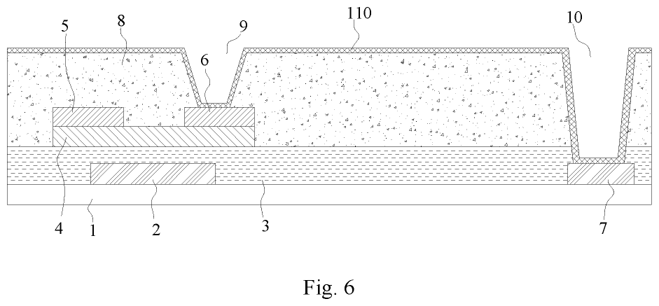

In step S140, as shown in FIGS. 6 to 11, a pattern 11 of a first conductive layer is formed on the passivation layer 8, the first conductive layer 11 covering the first via hole 9 and the second via hole 10.

In this embodiment, the first conductive layer 11 may be connected to the drain 6 of the thin film transistor through the first via hole 9, that is, the first conductive layer 11 may extend along the inner wall of the first via hole 9 and cover the drain 6 exposed by the first via hole 9. At the same time, the first conductive layer 11 may also be connected to the common pad 7 of the peripheral circuit through the second via hole 10, that is, the first conductive layer 10 also extends along the inner wall of the second via hole 10 and covers the common pad 7 exposed by the second via hole 10. The first conductive layer 11 may be made of a transparent conductive material, for example, indium tin oxide. Of course, the first conductive layer 11 may also be made of other conductive materials, which will not be enumerated here.

In step S150, as shown in FIG. 11, a pattern 12 of a reflective metal layer and a pattern 13 of a second conductive layer are formed on the pattern 11 of the first conductive layer. The second conductive layer 13 covers the second via hole 10.

In this embodiment, the reflective metal layer pattern 12 may directly cover the first conductive layer pattern 11 and may be located in the display area to reflect light in the display area. Materials for the reflective metal layer includes metals or alloy materials with high reflectivity such as aluminum, silver, molybdenum-aluminum alloy, aluminum-neodymium alloy, and the like. Of course, the material of the reflective metal layer 12 is not limited to the materials listed above, and other materials may also possible, which will not be enumerated here. The pattern 12 of the reflective metal layer may be the same as the pattern of the pixel electrode, that is, the reflective metal layer 12 may be a portion of the pixel electrode, and the reflective metal layer 12 may cover the first via hole 9 and be electrically connected to the drain 6 of the thin film transistor through the first conductive layer 11.

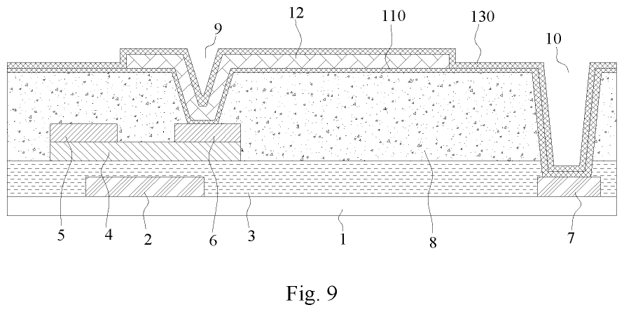

As shown in FIG. 9, in the process of forming the second conductive layer pattern 13, the formed second conductive layer may cover the reflective metal layer pattern 12 and the region of the first conductive layer 11 that is not covered by the reflective metal layer pattern 12, and the second conductive layer may be connected to the common pad 7 through the first conductive layer 11. Of course, the second conductive layer may also cover other regions, which is not limited herein. The second conductive layer may be formed of the same transparent conductive material as the first conductive layer, for example, indium tin oxide, which is advantageous for simplifying the manufacturing process. Of course, the second conductive layer 13 may also be made of other materials, which is not limited herein.

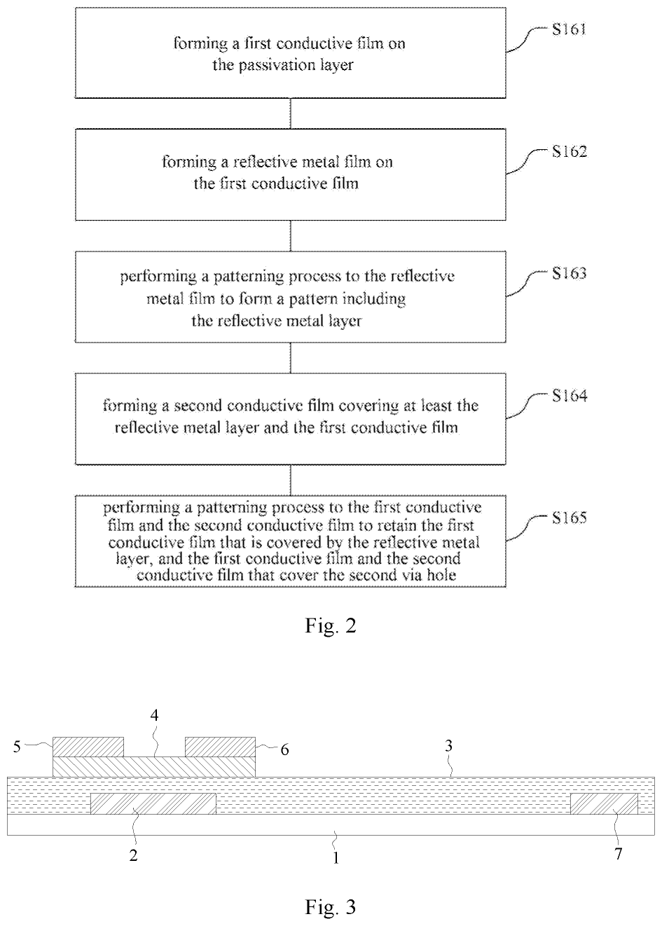

In an embodiment of the present disclosure, as shown in FIG. 2, the pattern 11 of the first conductive layer, the pattern 13 of the second conductive layer, and the pattern 12 of the reflective metal layer may be formed by the following steps:

S161, as shown in FIG. 6, forming a first conductive film 110 on the passivation layer 8. In an embodiment, the first conductive film 110 can be formed by various methods including, but not limited to, deposition, coating, sputtering, etc. The material of the first conductive film 110 may be a transparent conductive material such as indium tin oxide or other materials.

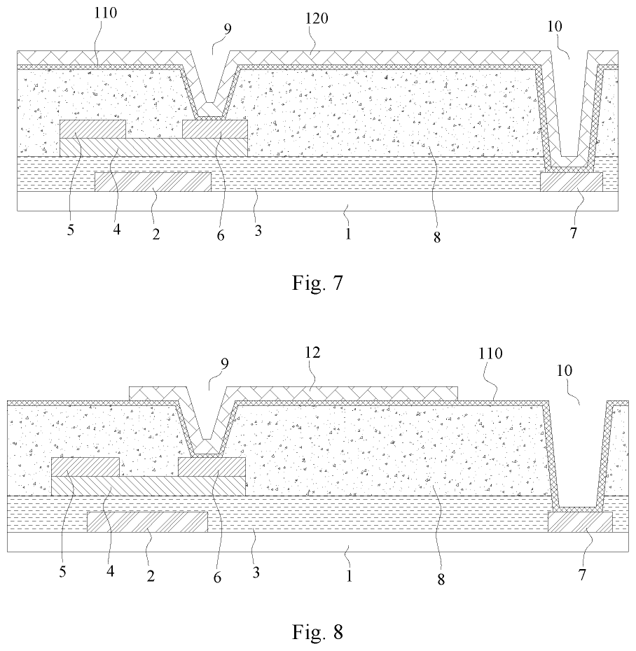

Step S162, as shown in FIG. 7, forming a reflective metal film 120 on the first conductive film. In an embodiment, the reflective metal film 120 may cover the first conductive film 110. The reflective metal film 120 is formed by methods including, but not limited to, deposition, coating, sputtering, etc. The material of the reflective metal film 120 may include metal or alloy materials with high reflectivity as described above, which are not described in detail herein.

Step S163, as shown in FIG. 8, performing a patterning process on the reflective metal film 120 to form a pattern 12 of the reflective metal layer. In an embodiment, the patterning process in step S163 may be a classical mask process in the art, which may include steps of photoresist coating, exposure, development, etching, photoresist stripping, etc., and certainly may also be a mask process employing ions peeling technology, as long as it can remove specific regions of the reflective metal film 120 to form the pattern 12 of the reflective metal layer.

Step S164, as shown in FIG. 9, forming a second conductive film 130 covering at least the pattern 12 of the reflective metal layer and the first conductive film 110. In this embodiment, methods for forming the second conductive film 130 may refer to those for forming the first conductive film 110, including but not limited to deposition, coating, sputtering, etc. The second conductive film 130 and the first conductive film 110 may be made of the same material, including but not limited to a transparent conductive material such as indium tin oxide.

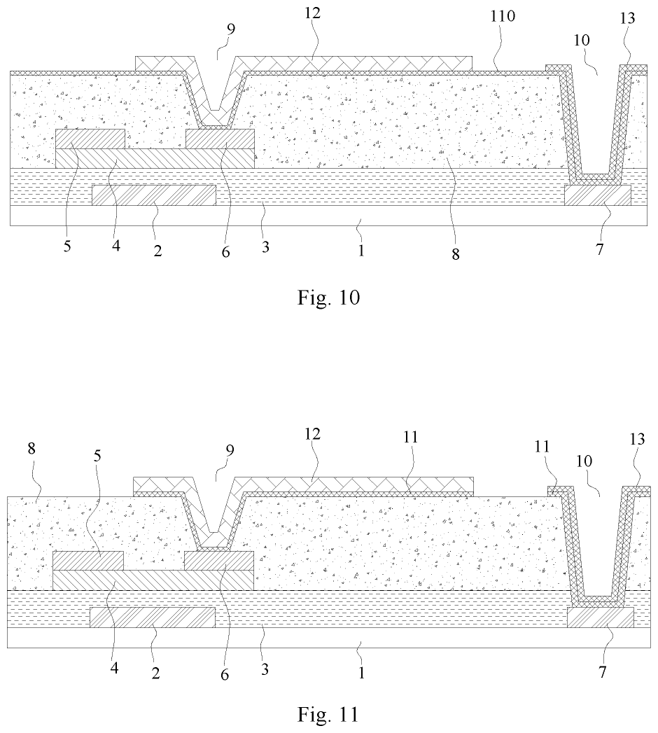

S165, as shown in FIGS. 10 and 11, performing a patterning process to the first conductive film 110 and the second conductive film 130 to retain a portion of the first conductive film 110 that is covered by the reflective metal layer pattern 12, and portions of the first conductive film 110 and the second conductive film 130 that cover the second via hole 10m, so as to obtain a first conductive layer pattern 11 and a second conductive layer patter 13.

In an embodiment, performing a patterning process to the first conductive film 110 and the second conductive film 130 may include the following steps: as shown in FIG. 10, performing a patterning process to the second conductive film 130 to remove a portion of the second conductive film 130 that does not cover the second via hole 10 to obtain the second conductive layer pattern 13, and as shown in FIG. 11, performing a photolithography process to the first conductive film 110 to remove a portion of the first conductive film 110 that is not covered by the reflective metal layer pattern 12 and does not cover the second via hole 10 to obtain the first conductive layer pattern 11.

After removing the second conductive film 130 not covering the second via hole 10, at least the reflective metal layer pattern 12 can be exposed in the display area, and only a portion of the second conductive film 130 that covers the second via hole 10 is retained in the non-display area to form the second conductive layer pattern 13. If the first conductive film 110 at the position where the second via hole 10 climbs is etched or damaged when the reflective metal layer pattern 12 is being formed, the second conductive layer pattern 13 covering the second via hole 10 can ensure a good contact at the second via hole 10.

The patterning process in the step S165 may be a classical mask process in the art and may include steps of photoresist coating, exposure, development, etching, photoresist stripping, etc., and certainly may also be a mask process employing ions peeling technology, which is not limited herein, as long as it can remove a portion of the second conductive film 130 that does not cover the second via hole 10 to form the second conductive layer pattern 13, and a portion of the first conductive film 110 that is not covered by the reflective metal layer pattern 12 and does not cover the second via hole 10. In particular, if the first conductive film 110 and the second conductive film 130 are formed of the same material, the same etching solution can be used when the above classical mask process is employed, which is advantageous for simplifying the process and improving the working efficiency.

It is to be noted that the above is only illustrative description of the manners for forming the first conductive layer pattern 11, the second conductive layer pattern 13, and the reflective metal layer pattern 12. In other embodiments, other processes such as printing may be used to form the first conductive layer pattern 11, the second conductive layer pattern 13, and the reflective metal layer pattern 12. For example, the first conductive layer 11 may be first formed on the passivation layer 8 by a printing process, and then the reflective metal layer 12 and the second conductive layer 13 may be separately formed by printing on the first conductive layer 11. Therefore, no particular limitation is imposed on the process of forming the first conductive layer pattern 11, the second conductive layer pattern 13, and the reflective metal layer pattern 12 in the present disclosure.

It can be understood from embodiments of the disclosure that the formed first conductive layer pattern 11 may include a first conductive sub-pattern and a second conductive sub-pattern. The first conductive sub-pattern is connected to the drain 6 of the thin film transistor through the first via hole 9, and the second conductive sub-pattern is connected to the common pad 7 of the peripheral circuit through the second via hole 10. In addition, the formed reflective metal layer pattern 12 and the first conductive sub-pattern may overlap and cover the first via hole 9, the second conductive sub-pattern and the second conductive layer pattern 13 may overlap each other and cover the second via hole 10. It is to be noted that although the steps of the method in embodiments of the present disclosure are described in a specific order in the drawings, this does not require or imply that these steps must be performed in the specific order, or that all the illustrated steps must be performed to achieve a desired result. In some embodiments, certain steps may be omitted, multiple steps may be combined into one step for execution, and/or one step may be decomposed into multiple steps for execution, and so on.

Another embodiment of the present disclosure provides an array substrate, which may include a display area and a non-display area. As shown in FIG. 11, the array substrate of an embodiment may include a base substrate 1, a thin film transistor, a peripheral circuit. a passivation layer 8, a first via hole 9, a second via hole 10, a first conductive layer pattern, a second conductive layer pattern, and a reflective metal layer pattern.

The base substrate 1 may have a display area and a non-display area, the display area of the base substrate 1 may correspond to an area of the array substrate for displaying an image, and the non-display area of the base substrate 1 may correspond to an area of the array substrate not for displaying an image. The non-display area may be located at the periphery of the display area.

In an embodiment of the present disclosure, the thin film transistor may be disposed in the display area. The thin film transistor may include a gate 2, a gate insulating layer 3, an active layer 4, a source 5, a drain 6, etc. For a detailed configuration of the thin film transistor, reference may be made to a thin film transistor in the prior art, and details are not described herein.

In an embodiment, a peripheral circuit may be disposed in the non-display area. The peripheral circuit may include a common pad 7 for connecting to a driving circuit board, and may also include other structures, which are not described herein in detail.

It is to be noted that, the gate 2 and the common pad 7 may be disposed in the same layer and may be formed on the base substrate 1 by a pattern using only one mask, which does not mean that the gate 2 and the common pad 7 can only be disposed in the same layer. They may be arranged in other ways.

In an embodiment, the passivation layer 8 may cover the thin film transistor and the peripheral circuit described above, and the passivation layer 8 may be formed of an insulating material so as to protect the thin film transistor and the peripheral circuit.

In an embodiment, the first via hole 9 may be a via hole for realizing electrical connections between the drain 6 of the thin film transistor and other elements, which may be located in the display area and penetrate the passivation layer 8 to expose the drain of the thin film transistor. Of course, the first via hole 9 is not limited to the via hole exposing the drain electrode 6 as described above, and may also be other via holes in the display area. For example, the first via hole may also be a via hole exposing the source of the thin film transistor. No limitation is imposed on the first via hole in the present disclosure.

In an embodiment, the second via hole 10 may be a via hole for realizing electrical connections between the common pad 7 of the peripheral circuit and other elements, which may be located in the non-display area, penetrate the passivation layer 8, and further penetrate the gate insulating layer 3 to expose the common pad 7. Of course, the second via hole 10 is not limited to the via hole exposing the common pad 7, and may also be other via holes in the non-display area. No limitation is imposed on the second via hole in the present disclosure.

In an embodiment, for the formation of the first conductive layer pattern, reference may be made to the foregoing embodiments of the method for manufacturing an array substrate, in which the first conductive layer pattern may include portions of the first conductive film 110 retained in the display area and the non-display area.

In an embodiment, for the formation of the second conductive layer pattern, reference may be made to the foregoing embodiments of the method for manufacturing an array substrate, in which the second conductive layer pattern may be a portion of the second conductive film 130 retained in the non-display area, and the second conductive layer pattern may coincide with the second via hole 10, that is, the second conductive layer pattern 13 and the first conductive layer pattern 11 may overlap each other in the non-display area. The first conductive layer pattern 11 and the second conductive layer pattern 13 may be formed of the same transparent conductive material such as indium tin oxide. If the first conductive layer pattern 11 and the second conductive layer pattern 13 are made of the same material, their patterns may be an integrated structure.

In an embodiment, the reflective metal layer pattern may cover and coincide with the first conductive layer pattern, both of which may be electrically conductive, so that the reflective metal layer pattern and the first conductive layer pattern may serve as the pixel electrode. Meanwhile, the reflective metal layer pattern can further reflect light, thereby providing a light source for imaging of the array substrate.

A further embodiment of the present disclosure provides a display device including the array substrate described in any of the foregoing embodiments.

For the array substrate and the display device provided by the embodiments of the present disclosure, the array substrate can be manufactured using the method for manufacturing an array substrate as described in the foregoing embodiments. The first via hole 9 is protected by the first conductive film pattern to prevent etching to the metal exposed by the first via hole 9 when the reflective metal layer pattern is being formed. At the same time, the electrical connection at the second via hole 10 is consolidated and reinforced using the second conductive layer pattern to compensate possible etching to the metal exposed by the second via hole 10 and possible etching occurring at the position where the second via hole 10 climbs when the second conductive layer pattern is being formed, so that poor contact at the first via hole 9 and the second via hole 10 resulting from the formation of the reflective metal layer pattern can be avoided or reduced, which is advantageous for improving the yield.

Other embodiments of the disclosure will be easily conceived by those skilled in the art after considering the specification and practicing the embodiments disclosed herein. The disclosure is intended to encompass any variation, usage or adaptation of the disclosure, which follows the general principle of the present disclosure and includes common knowledge or conventional technical measures in this technical field that are not disclosed in the disclosure. The specification and embodiments are considered to be illustrative only. The real scope and spirit of the disclosure are indicated by the appended claims.

1. A method for manufacturing an array substrate, comprising:
forming a thin film transistor and a peripheral circuit,
forming a passivation layer covering at least the thin film transistor and the peripheral circuit,
forming a first via hole penetrating the passivation layer and exposing part of a drain of the thin film transistor, and a second via hole penetrating the passivation layer and exposing part of the peripheral circuit,
forming a first conductive layer pattern on the passivation layer, the first conductive layer pattern covering the first via hole and the second via hole, and
forming a reflective metal layer pattern and a second conductive layer pattern on the first conductive layer pattern, the second conductive layer pattern covering the second via hole.

2. The method for manufacturing an array substrate according to claim 1,
wherein forming the first conductive layer pattern, the second conductive layer pattern, and the reflective metal layer pattern comprises:
forming a first conductive film on the passivation layer,
forming a reflective metal film on the first conductive film,
performing a patterning process to the reflective metal film to form the reflective metal layer pattern,
forming a second conductive film covering at least the reflective metal layer pattern and the first conductive film, and
performing a patterning process to the first conductive film and the second conductive film to retain a portion of the first conductive film covered by the reflective metal layer pattern, and a portion of the first conductive film and a portion of the second conductive film that cover the second via hole.

3. The method for manufacturing an array substrate according to claim 2, wherein performing a patterning process to the first conductive film and the second conductive film comprises:
performing a patterning process to the second conductive film to remove a portion of the second conductive film that does not cover the second via hole, and
performing a patterning process to the first conductive film to remove a portion of the first conductive film that is not covered by the reflective metal layer pattern and does not cover the second via hole.

4. The method for manufacturing an array substrate according to claim 1, wherein the first conductive layer pattern comprises a first conductive sub-pattern and a second conductive sub-pattern, the first conductive sub-pattern being connected to the drain of the thin film transistor via the first via hole, and the second conductive sub-pattern being connected to a common pad of the peripheral circuit via the second via hole.

5. The method for manufacturing an array substrate according to claim 1, wherein a material of the first conductive layer pattern is the same as that of the second conductive layer pattern.

6. The method for manufacturing an array substrate according to claim 5,
wherein the first conductive layer pattern and the second conductive layer pattern both comprise a transparent conductive material.

7. The method for manufacturing an array substrate according to claim 4, wherein the reflective metal layer pattern and the first conductive sub-pattern overlap each other and cover the first via hole.

8. The method for manufacturing an array substrate according to claim 4, wherein the second conductive sub-pattern and the second conductive layer pattern overlap each other and cover the second via hole.

9. The method for manufacturing an array substrate according to claim 1, wherein the reflective metal layer constitutes a part of a pixel electrode of the array substrate.

10. An array substrate comprising:
a base substrate,
a thin film transistor on the base substrate,
a peripheral circuit on the base substrate,
a passivation layer covering at least the thin film transistor and the peripheral circuit,
a first via hole penetrating the passivation layer and exposing part of a drain of the thin film transistor,
a second via hole penetrating the passivation layer and exposing part of the peripheral circuit,
a first conductive layer pattern disposed on the passivation layer and covering the first via hole and the second via hole,
a second conductive layer pattern disposed on the passivation layer and covering the second via hole, and
a reflective metal layer pattern disposed on the first conductive layer pattern and covering the first via hole.

11. The array substrate according to claim 10, wherein the first conductive layer pattern and the second conductive layer pattern are made of a same material.

12. The array substrate according to claim 11, wherein the first conductive layer pattern and the second conductive layer pattern both comprise a transparent conductive material.

13. The array substrate according to claim 10, wherein the first conductive layer pattern comprises a first conductive sub-pattern and a second conductive sub-pattern, the first conductive sub-pattern being connected to the drain of the thin film transistor via the first via hole, and the second conductive sub-pattern being connected to a common pad of the peripheral circuit via the second via hole.

14. The array substrate according to claim 13, wherein the reflective metal layer pattern and the first conductive sub-pattern overlap each other and cover the first via hole.

15. The array substrate according to claim 13, wherein the second conductive sub-pattern and the second conductive layer pattern overlap each other and cover the second via hole.

16. The array substrate according to claim 10, wherein the reflective metal layer constitutes a part of a pixel electrode of the array substrate.

17. A display device comprising the array substrate of any of claim 10.

18. The display device according to claim 17, wherein the first conductive layer pattern comprises a first conductive sub-pattern and a second conductive sub-pattern, the first conductive sub-pattern being connected to the drain of the thin film transistor via the first via hole, and the second conductive sub-pattern being connected to a common pad of the peripheral circuit via the second via hole.

19. The display device according to claim 18, wherein the reflective metal layer pattern and the first conductive sub-pattern overlap each other and cover the first via hole.

20. The display device according to claim 17, wherein the reflective metal layer constitutes a part of a pixel electrode of the array substrate.
